(19) United States
(12) Patent Application Publication
(10) Pub. No.: US 2006/0108598 A1
(43) Pub. Date: May 25, 2006

(54) Gallium nitride-based light-emitting device

(76) Inventors: Mu-Jen Lai, Chungli City (TW); Yueh-Hsun Yang, PingCheng City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/023,493

(22) Filed: Dec. 29, 2004

(30) Foreign Application Priority Data
Nov. 23, 2004 (TW) 093218812

(51) Int. Cl. H01L 33/00

(52) U.S. Cl. 257/103; 257/99

(57) ABSTRACT

A light-emitting gallium nitride-based III-V group compound semiconductor device with enhanced brightness includes a substrate, a first-type conductive semiconductor layer, a light-emitting layer, a second-type conductive semiconductor layer, a transparent conductive layer, and two electrodes. During the manufacturing process of chips, a single or a pair of diamond scribing tool inclined in a certain angle is/are used, in combination with following breaking procedures, to make four sides of the chips of light emitting diode are trapezoid or parallelogram in the side view. Therefore, the external quantum efficiency of the light-emitting device is increased.

### BACKGROUND OF THE INVENTION

The present invention relates to a gallium nitride-based III-V group compound semiconductor light-emitting device with enhanced external quantum efficiency, especially to a light emitting device that the sides-emitting extracting efficiency thereof are improved.

Refer to FIG. 1, the epitaxial structure of conventional gallium nitride-based III-V group compound semiconductor light-emitting device 1′ is disclosed. The present invention includes a sapphire substrate 10′, a gallium nitride buffer layer 15′, a n-type gallium nitride contact layer 20′, an indium gallium nitride (InGaN) emitting layer 30′, a p-type gallium nitride layer 40′, a p-type gallium nitride contact layer 42′. Then remove part of the a n-type gallium nitride contact layer 20′, an indium gallium nitride (InGaN) emitting layer 30′, a p-type gallium nitride layer 40′, a p-type gallium nitride contact layer 42′ so as to make part of the surface of the n-type gallium nitride contact layer 20′ expose. This step of manufacturing process is called mesa etching. Then a transparent conductive layer 50′ made of Ni/Au is formed over the p-type gallium nitride contact layer 42′ while a p-type metal electrode 70′ is over the transparent conductive layer 50′. And a n-type metal electrode 60′ is over the n-type gallium nitride contact layer 20′ to form a horizontally located electrodes. In such structure, the thickness of the sapphire substrate 10′ is approximately from 75 μm to 95 μm while the thickness of the epitaxial structure is approximately from 4 μm to 10 μm while the chips with vertical edge in side view.

When turn-on current is applied to the p-type metal electrode 70′ and the n-type metal electrode 60′ so as to make the indium gallium nitride emitting layer 30′ emit light. The path of the emitted light is shown in FIG. 2. Part of the light is radiated directly as path A and part of the light is radiated after several times of reflection, as path B. Part of the light emitted forward is not only shielded by the p-type metal electrode 70′ and the n-type metal electrode 60′, but also is absorbed partially by the transparent conductive layer 50′.

Furthermore, the refractive index of the epitaxial structure of gallium nitride is 2.4, the refractive index of the sapphire substrate is 1.77, and the refractive index of the packaging resin is 1.5. Due to the waveguide effect, part of the light emitting from the light-emitting layer is reflected by the sapphire substrate and the packaging resin. And chips having the sapphire substrate 10′ with vertical edge in side view have smaller total reflection angle. Therefore, the light emitting from the light-emitting layer is reflected multiple times and then absorbed by the multi-layer epitaxial structure of gallium nitride. Therefore, the light extracting efficiency is decreased.

Moreover, due to high hardness of the sapphire substrate, general dicing procedure of the LED chips includes following steps:

the sapphire substrate is grinded to the desired thickness—about 80 to 100 um. Then a diamond scribing tool is used to make a scribing mark with width of 5 um and depth of 10 um on the sapphire substrate along a cutting line. The scribing mark leads to a crack with depth of 25 um formed on the sapphire substrate. Then a breaking machine is used to cut dies along the scribing mark. The side view of the dies is with perpendicular edge because that the edge of the diamond scribing tool is perpendicular to the surface of the dies, in angle of 90 degrees.

There is a need to increase the light extracting efficiency of sides of the gallium nitride-based III-V group compound semiconductor light-emitting device.

### SUMMARY OF THE INVENTION

Therefore it is a primary object of the present invention to proved a gallium nitride-based III-V group compound semiconductor light-emitting device with enhanced external quantum efficiency. Through a design of appearance, the light-emitting extracting efficiency from sides of the light-emitting device is improved. The side view of the light-emitting device is a tetragon without two sides perpendicular with each other such as parallelogram or trapezoid.

In order to achieve above object, the present invention consists of a substrate, a first-type conductive semiconductor layer, a light-emitting layer, a second-type conductive semiconductor layer, a transparent conductive layer, and two electrodes. During the manufacturing process of chips, a single or a pair of diamond scribing tool inclined in a certain angle is/are used, in combination with following breaking procedures, to make four sides of the chips of light emitting diode are parallelogram in the side view. Therefore, the external quantum efficiency of the light-emitting device is increased.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a schematic drawing of a prior art of a gallium nitride-based III-V group compound semiconductor light-emitting device;

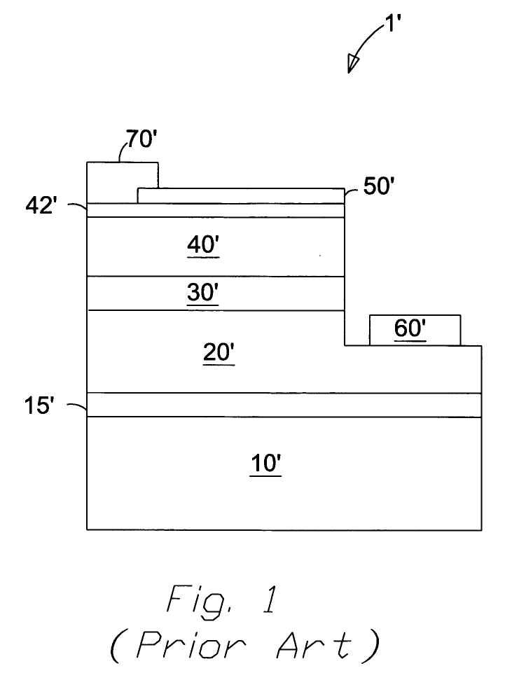

FIG. 2 is a diagram showing the light path emitted from a light-emitting layer of a prior art;

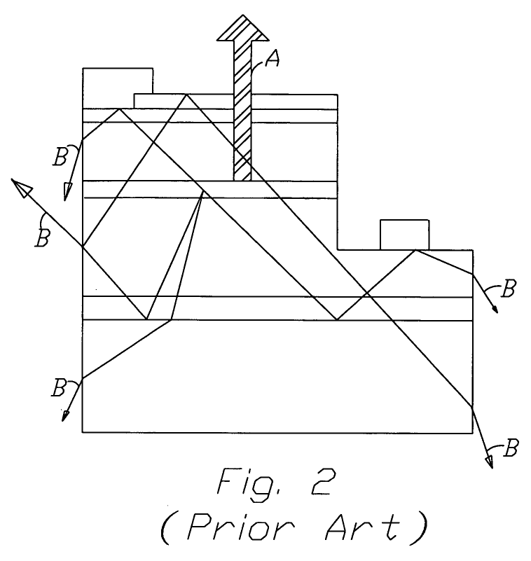

FIG. 3A is a schematic drawing showing dicing of an embodiment in accordance with the present invention;

FIG. 3B is a diagram showing structure of an embodiment in accordance with the present invention;

FIG. 4A is a schematic drawing showing dicing of another embodiment in accordance with the present invention; and

FIG. 4B is a diagram showing structure of another embodiment in accordance with the present invention.

### DETAILED DESCRIPTION OF THE PREFFERED EMBODIMENT

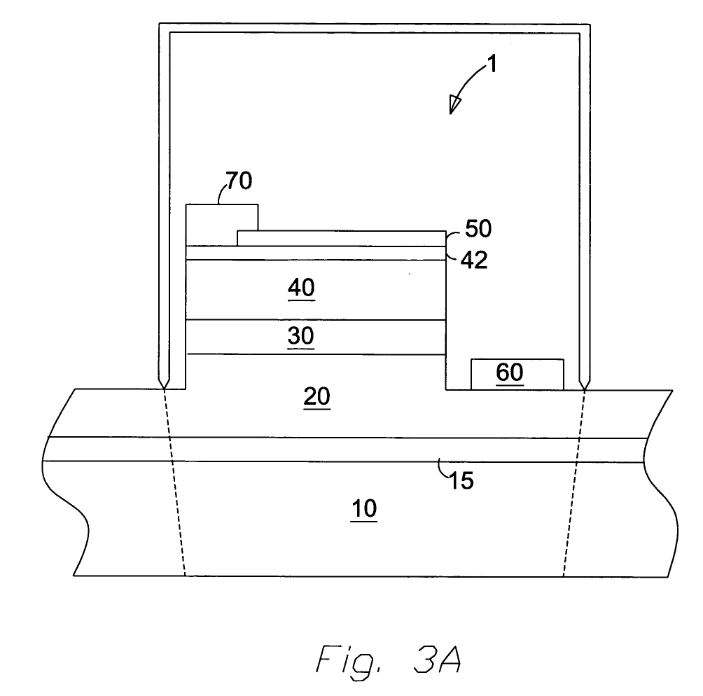

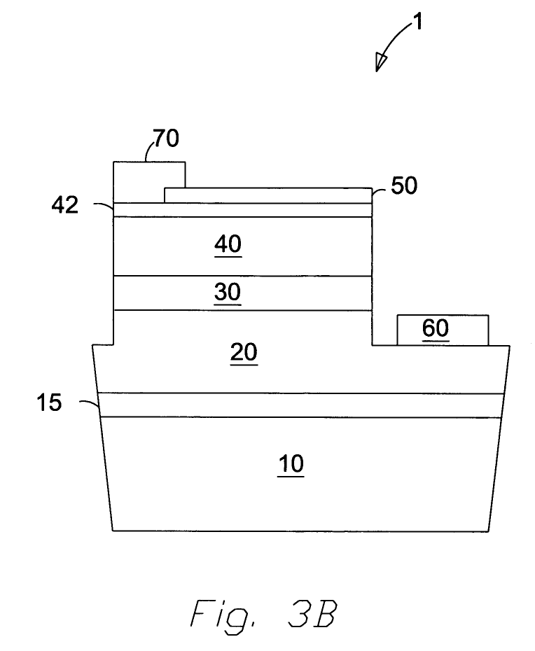

Refer to FIG. 3A & FIG. 3B, a preferred embodiment of the present invention is disclosed. A gallium nitride-based III-V group compound semiconductor light-emitting device 1 in accordance with the present invention consists of a sapphire substrate 10, a gallium nitride buffer layer 15, a n-type gallium nitride contact layer 20, an indium gallium nitride (InGaN) emitting layer 30, a p-type gallium nitride layer 40, and a p-type gallium nitride contact layer 42. Then remove part of the a n-type gallium nitride contact layer 20, an indium gallium nitride (InGaN) emitting layer 30, a p-type gallium nitride layer 40, a p-type gallium nitride contact layer 42 so as to make part of the surface of the n-type gallium nitride contact layer 20 expose. Thus a transparent conductive layer 50 made of Ni/Au is formed over the p-type gallium nitride contact layer 42 while a p-type metal electrode 70 is over the transparent conductive layer 50. And a n-type metal electrode 60 is over the n-type gallium nitride contact layer 20 to form a horizontally located electrodes.

Moreover, the present invention features on that the side view of the combination of sapphire substrate 10 and the epitaxial layers 15˜42 of the light-emitting device 1 is a shape without two sides perpendicular with each other such as a trapezoid or a parallelogram so as to enhance the light-emitting extracting efficiency of sides of the light-emitting device 1. The general procedure of dicing in accordance with the present invention is described as following. The sapphire substrate is grinded to the desired thickness—about 80 to 100 um. Then a pair of diamond scribing tool is used to make a scribing mark with width of 5 um and depth of 10 um on four sides of the sapphire substrate along a cutting line. Owing to a certain raked angle of the diamond scribing tool, the scribing mark leads to a crack with depth of 25 um formed on the sapphire substrate. Then a breaking machine is used to cut dies along the scribing mark. The side view of the dies is trapezoid or parallelogram.

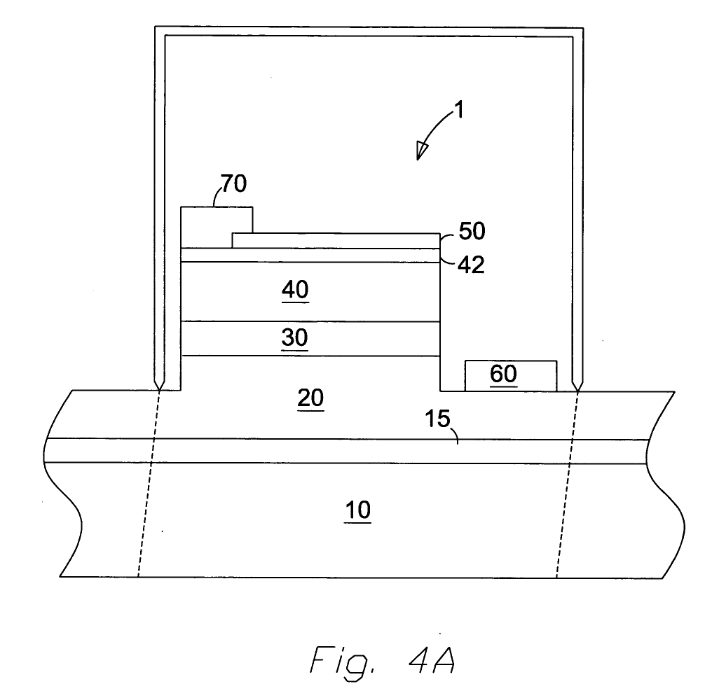

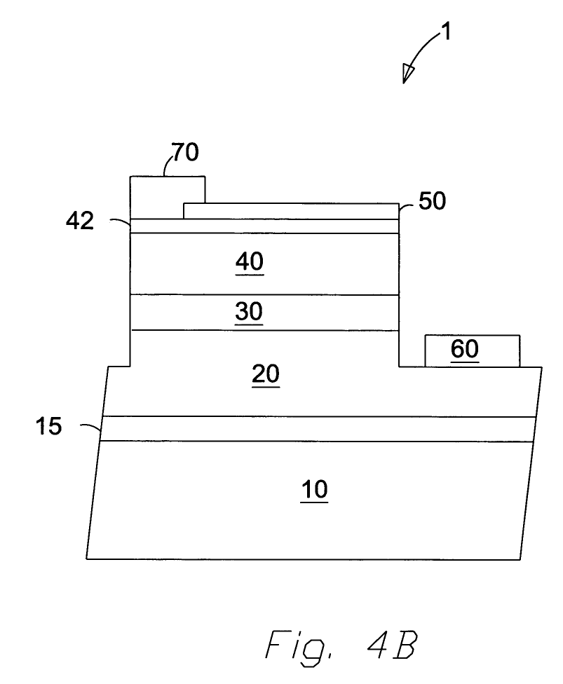

Refer to FIG. 4A & FIG. 4B, another embodiment of the present invention is disclosed. The difference between this embodiment and above one is that the shape of the side view of the combination of sapphire substrate 10 and the epitaxial layers 15˜42 is parallelogram, instead of rectangle, so as to increase light-emitting extracting efficiency of sides of the light-emitting device 1. The cutting procedure of the LED chips in accordance with the present invention is described as following: due to high hardness of the sapphire substrate, general procedure of dicing includes following steps:

the sapphire substrate is grinded to the desired thickness—about 80 to 100 um. Then a diamond scribing tool is used to make a scribing mark with width of 5 um and depth of 10 um on four sides of the sapphire substrate along a cutting line. Owing to a certain raked angle of the diamond scribing tool, the scribing mark causes a crack with depth of 25 um formed on the sapphire substrate. Then a breaking machine is used to cut dies along the scribing mark. The side view of the dies is parallelogram.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

What is claimed is:

1. A gallium nitride-based III-V group compound semiconductor light-emitting device with enhanced external quantum efficiency comprising:
a substrate; and
a semiconductor stacked structure arranged over said substrate;
wherein said substrate is cut into a shape without two sides perpendicular with each other in side view; at least one diamond scribing toll is used to make a scribing mark on said sapphire substrate along at least one cutting line; the scribing mark causes a crack raked in a certain angle on said sapphire substrate; dies are formed by breaking along said scribing mark.

2. The device according to claim 1, wherein a side view of the combination of said substrate and said semiconductor stacked structure is a trapezoid that is formed by a pair of diamond scribing tool inclined in a certain angle.

3. The device according to claim 1, wherein a side view of said substrate is a trapezoid that is formed by a pair of diamond scribing tool inclined in a certain angle.

4. The device according to claim 1, wherein a side view of the combination of said substrate and said semiconductor stacked structure is a parallelogram that is formed by a pair of diamond scribing tool inclined in a certain angle

5. The device according to claim 1, wherein a side view of said substrate is a parallelogram that is formed by a pair of diamond scribing tool inclined in a certain angle.

6. The device according to claim 1, wherein said shape without two sides perpendicular with each other is a trapezoid that length of the base is less than length of the upper.

7. The device according to claim 1, wherein a side view of said substrate is a parallelogram that is formed by a single diamond scribing tool inclined in a certain angle.

8. The device according to claim 1, wherein a side view of the combination of said substrate and said semiconductor stacked structure is a parallelogram that is formed by a single diamond scribing tool inclined in a certain angle

9. The device according to claim 1, wherein said semiconductor stacked structure having a first-type conductive semiconductor layer, a light-emitting layer and a second-type conductive semiconductor layer.

10. The device according to claim 1, wherein a transparent conductive oxide layer is arranged over said semiconductor stacked structure.

11. The device according to claim 9, wherein said first-type conductive semiconductor layer is made of gallium nitride (GaN), aluminum indium gallium nitride (AlInGaN), or indium gallium nitride (InGaN).

12. The device according to claim 9, wherein said second-type conductive semiconductor layer is made of gallium nitride (GaN), aluminum indium gallium nitride (AlInGaN), or indium gallium nitride (InGaN).

13. The device according to claim 9, wherein said light-emitting layer is formed of a nitride compound semiconductors having indium.

14. The device according to claim 10, wherein said transparent conductive layer is made of an indium oxide, tin oxide, indium molybdenum oxide, indium cerium oxide, zinc oxide, indium zinc oxide, magnesium zinc oxide, tin cadmium oxide, or indium tin oxide.

15. The device according to claim 10, wherein said transparent conductive layer is made by at least one of followings: Ni/Au, Pt, TiN, TaN, CuAlO, LaCuOS, CuGaO, SrCu₂O, or Au in combination with NiO, IrO, RhO, RuO.

16. A light-emitting gallium nitride-based m-v group compound semiconductor device with enhanced external quantum efficiency comprising
a substrate;
a first-type conductive semiconductor layer over said substrate;
a light-emitting layer over said first-type conductive semiconductor layer,
a second-type conductive semiconductor layer over said light-emitting layer;
a transparent conductive layer over said second-type conductive semiconductor layer;
a first electrode over said first-type conductive semiconductor layer; and
a second electrode over said transparent conductive layer;
wherein said substrate is cut into a shape without two sides perpendicular with each other in side view.

17. The device according to claim 16, wherein a side view of the combination of a first-type conductive semiconductor layer, a light-emitting layer, a second-type conductive semiconductor layer, and said substrate is a trapezoid that is formed by a pair of diamond scribing tool inclined in a certain angle.

18. The device according to claim 16, wherein a side view of the combination of a first-type conductive semiconductor layer and said substrate is a trapezoid that is formed by a pair of diamond scribing tool inclined in a certain angle.

19. The device according to claim 17, wherein said trapezoid having two sides that one side on said substrate is shorter than the other side on said first-type conductive semiconductor layer.

20. The device according to claim 18, wherein said trapezoid having two sides that one side on said substrate is shorter than the other side on said first-type conductive semiconductor layer.

21. The device according to claim 16, wherein a side view of the combination of a first-type conductive semiconductor layer, a light-emitting layer, a second-type conductive semiconductor layer, and said substrate is a parallelogram that is formed by a single diamond scribing tool inclined in a certain angle.

22. The device according to claim 16, wherein a side view of the combination of a first-type conductive semiconductor layer and said substrate is a parallelogram that is formed by a single diamond scribing tool inclined in a certain angle.

23. The device according to claim 16, wherein a side view of the combination of a first-type conductive semiconductor layer, a light-emitting layer, a second-type conductive semiconductor layer, and said substrate is a parallelogram that is formed by a pair of diamond scribing tool inclined in a certain angle.

24. The device according to claim 16, wherein a side view of the combination of a first-type conductive semiconductor layer and said substrate is a parallelogram that is formed by a pair of diamond scribing tool inclined in a certain angle.

25. The device according to claim 16, wherein said first-type conductive semiconductor layer is made of gallium nitride (GaN), aluminum indium gallium nitride (AlInGaN), or indium gallium nitride (InGaN).

26. The device according to claim 16, wherein said second-type conductive semiconductor layer is made of gallium nitride (GaN), aluminum indium gallium nitride (AlInGaN), or indium gallium nitride (InGaN).

27. The device according to claim 16, wherein said light-emitting layer is formed of a nitride compound semiconductors having indium.

28. The device according to claim 16, wherein said transparent conductive layer is made of an indium oxide, tin oxide, indium molybdenum oxide, indium cerium oxide, zinc oxide, indium zinc oxide, magnesium zinc oxide, tin cadmium oxide, or indium tin oxide.

29. The device according to claim 16, wherein said transparent conductive layer is made by at least one of followings: Ni/Au, Pt, TiN, TaN, CuAlO, LaCuOS, CuGaO, SrCu₂O, or Au in combination with NiO, IrO, RhO, RuO.
